(19) United States
(12) Patent Application Publication
(10) Pub. No.: US 2013/0240254 A1
(43) Pub. Date: Sep. 19, 2013

(54) PRINTED CIRCUIT BOARD AND METHOD FOR MANUFACTURING PRINTED CIRCUIT BOARD

(71) Applicants: XIAO-ZHAN PENG, Shenzhen City (CN); QIANG NIE, Shenzhen City (CN); CUI-CUI ZHANG, Shenzhen City (CN); JUN-CUI ZHANG, Shenzhen City (CN)

(72) Inventors: XIAO-ZHAN PENG, Shenzhen City (CN); QIANG NIE, Shenzhen City (CN); CUI-CUI ZHANG, Shenzhen City (CN); JUN-CUI ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/563,861

(22) Filed: Aug. 1, 2012

(30) Foreign Application Priority Data
Mar. 15, 2012 (CN) 201210067784.0

(51) Int. Cl. H05K 1/09; H05K 3/00

(52) U.S. Cl. 174/257; 29/829

(57) ABSTRACT

A printed circuit board includes a substrate, at least one pad on the substrate, and permanent mold coatings capable of coating on the copper foil. Each pad includes a copper foil and a solder resist coating on the substrate and surrounding the copper foil. The copper foil defines an opening. The opening is coated with solder resist, whereby the permanent mold coatings form a recess corresponding to the opening when coated on the copper foil. A method for manufacturing a printed circuit board is also provided.

### BACKGROUND

1. Technical Field

The present disclosure relates to printed circuit board and method for manufacturing printed circuit board.

2. Description of Related Art

Referring to FIGS. 4-5 a printed circuit board (PCB) 300 is formed by a layer of conducting material deposited on the surface of an insulating substrate 310. A plurality of pads 320 and printed wirings (such as copper tracks) 330 are designed on the substrate 310 for connecting electric component (not shown). Each pad 300 includes a copper foil 321 covering on the substrate and a solder resist 322 arranged around the copper foil 321. A permanent mold coating 324, such as solder paste, is coated on the copper foil 321 to hold the electronic components in place until the permanent mold coating 324 is melted.

However, during the typical manufacturing of the PCB 300, when the permanent mold coating 324 is coated on the copper foil 321, the permanent mold coating 324 is substantially convex shaped with the middle portion higher than the surrounding portion (see FIG. 5). As a result, when the electronic component is connected to the pad 320 by manually melting the leads of the electronic component to the permanent mold coating 324, it is difficult for the user to position the leads in the middle of the permanent mold coating 324 because of the convex shape.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the five views.

FIG. 1 is a partial perspective view of a printed circuit board in accordance with an embodiment.

FIG. 2 is a partially cross-sectional view of the printed circuit board of FIG. 1.

FIG. 3 is a flow chart of a method for manufacturing the printed circuit board of FIG. 1.

FIG. 4 is a partial perspective view of a related art printed circuit board.

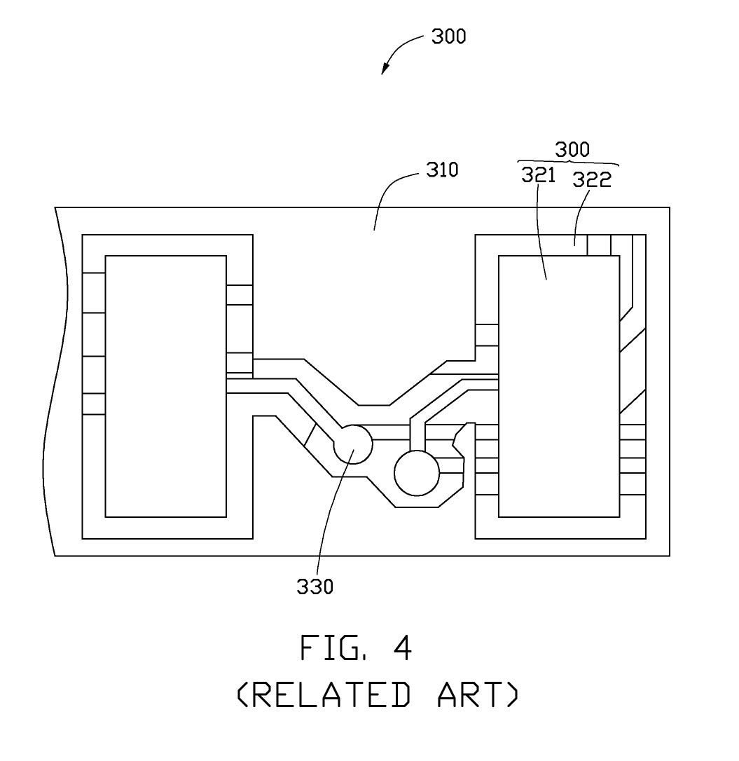

FIG. 5 is partially cross-sectional view of the related art printed circuit board of FIG. 4.

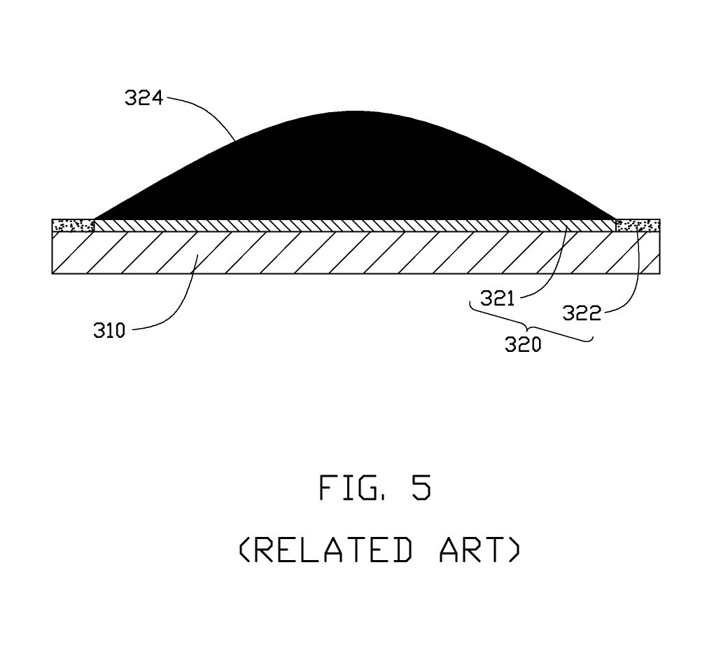

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

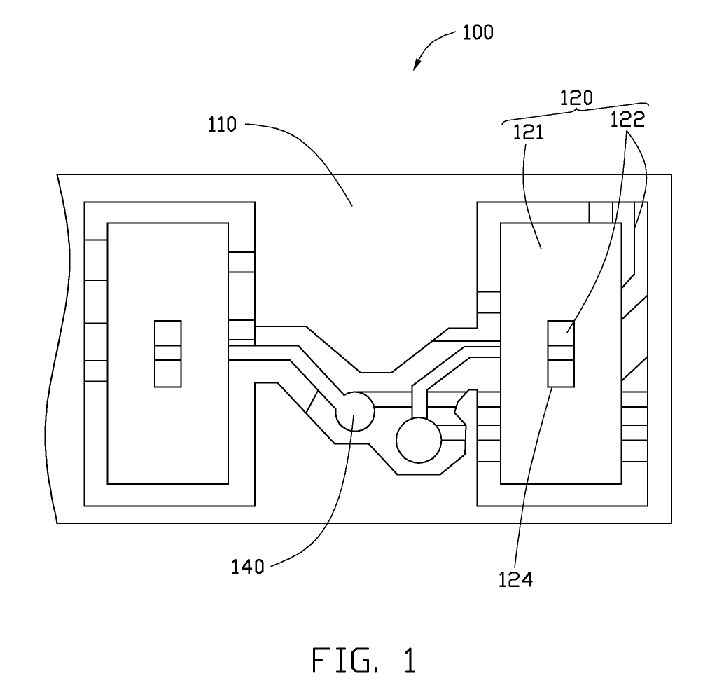

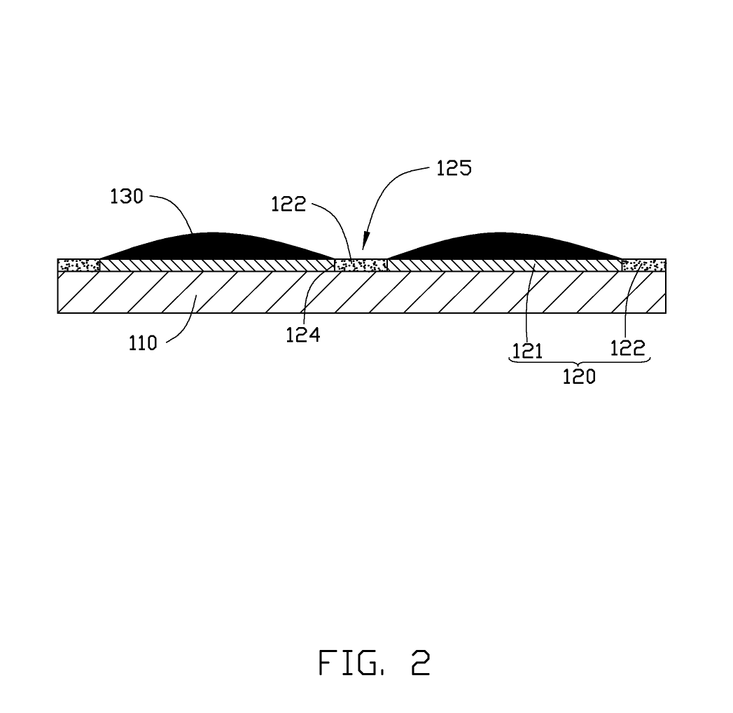

FIGS. 1-2, illustrate a printed circuit board (PCB) 100 of one embodiment. The PCB 100 includes a substrate 110, a plurality of pads 120 designed on the substrate 110, permanent mold coatings 130 coated on the pads 120, a plurality of copper tracks 140 for linking electronic components (not shown) soldered to the pads 120. In the embodiment, the substrate 110 used in printed circuit board 100 is a glass fiber reinforced (fiberglass) epoxy resin with copper foil bonded on to one or both sides.

Each pad 120 includes a copper foil 121 bonded to the substrate 110 and a solder resist 122 surrounding the copper foil 121. The copper foil 121 is substantially rectangular and defines an opening 124. The opening 124 is substantially rectangular and is arranged in the middle of the copper foil 121. The opening 124 is further coated with solder resist 122. The solder resist 122 is used to prevent the permanent mold coatings 130 from coating on the substrate 110. The solder resist 122 is green lacquer in the embodiment.

The permanent mold coatings 130 in the embodiment are solder paste. The permanent mold coatings 130 are coated on the copper foil 121 with surface mount technology (SMT), to protect the copper foil 121 and further to enhance welding performance of the pad 120. Because the opening 124 is defined in the middle of the copper foil 121 and is coated with the solder resist 122, the permanent mold coatings 130 only cover on the copper foil 121 and surround the opening 124 to form a recess 125. As a result, the permanent mold coatings 130 are dimple-shaped with the middle portion being recessed. By aligning the leads in the recess 125, the operator can easily position the leads of the electronic components and further accurately melt the leads with the pads 120. Furthermore, during the hot-melting process, the recess 125 receives the melted solder to avoid burrs being generated, and the soldered pads 120 are not needed to be washed.

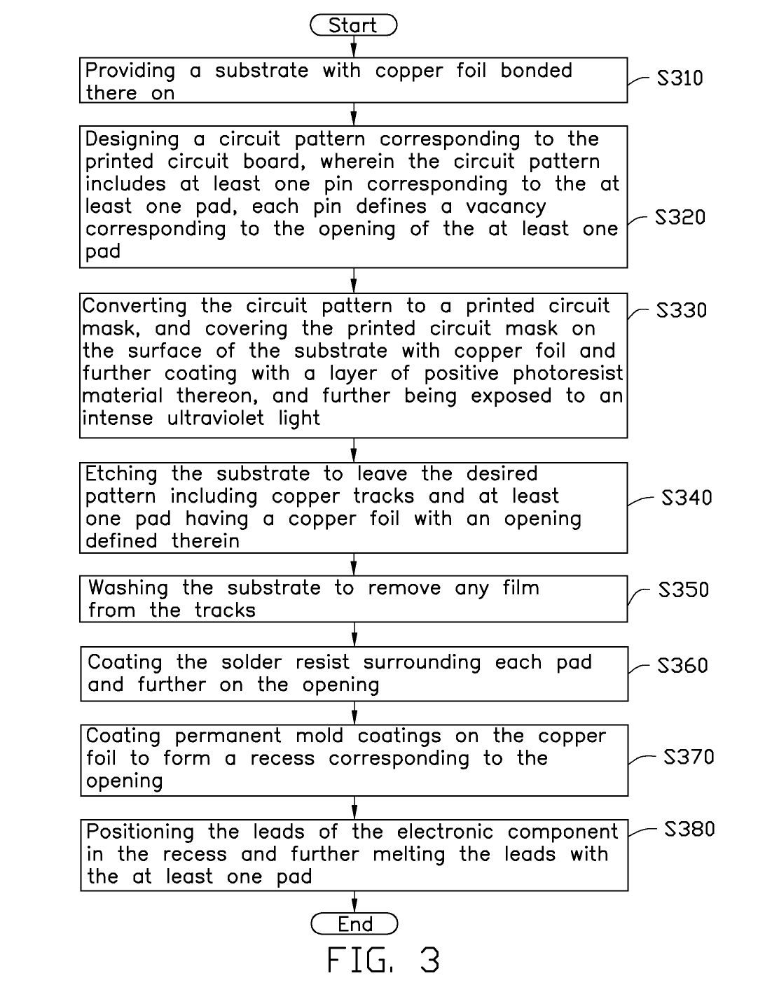

FIG. 3, is a flow chart of a method for manufacturing the PCB 100. The method includes the follow steps:

In step S310, a substrate 110 is provided. In the embodiment, the substrate 110 used in printed circuit board 100 is a glass fiber reinforced (fiberglass) epoxy resin with copper foil bonded on to one or both sides.

In step S320, a circuit pattern corresponding to the PCB 100 is designed. Each PCB has a unique function for a particular product and must be designed to perform that function in the space allotted. Board designers use computer-aided design systems with special software to layout the circuit pattern. The circuit pattern includes a plurality of pins corresponding to the pads 120 of the PCB 100 respectively. Each pin defines a vacancy corresponding to the opening 124 of the pads 120.

In step S330, the designed circuit pattern is converted to PCB layout, and the PCB layout is printed on a transparency and becomes known as a PCB mask. The PCB mask further covers on the surface of the substrate with copper foil (referred as the foil surface). The foil surface with the PCB mask pass through a vacuum chamber where a layer of positive photoresist material is pressed firmly onto the entire surface of the foil. A positive photoresist material is a polymer that has the property of becoming more soluble when exposed to ultraviolet light. After passing through the vacuum chamber, the foil surface covered with the PCB mask and photoresist material is exposed to an intense ultraviolet light. Because the mask is clear in the areas of the printed circuit pattern, the photoresist in those areas is irradiated and becomes very soluble.

In step S340, after being exposed to an intense ultraviolet light, the substrate 110 with copper foil is etched to leave the desired pattern including copper tracks 140 and pads 120 having copper foil 121 with an opening 124 defined therein.

In step S350, when removed from the etching solution, the substrate 110 is washed and a PCB eraser is used to remove any film from the tracks.

In step S360, the substrate 110 is further coated with the solder resist 122 to prevent the permanent mold coatings 130 from coating on the substrate 110 and the copper foil 121. In the embodiment, the solder resist 122 is coated surrounding each pad 120 and further coat on opening 124.

In step S370, the permanent mold coatings 130 coat on the copper foil 121 to protect the copper foil 121 from being oxidized and further to enhance welding performance of the pad 120. Because the opening 124 is defined in the middle of the copper foil 121 and is coated with solder resist 122, the permanent mold coatings 130 only cover on the copper foil 121 and surround the opening 124 to form a recess 125. As a result, the permanent mold coatings 130 are dimple-shaped with the middle portion being recessed.

In step S380, the leads of the electronic component is aligned with the recess 125, and further accurately being melt with the pads 120 to solder the electronic component to the PCB 100.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. A printed circuit board, comprising:
a substrate;
at least one pad on the substrate, each pad comprising a copper foil and a solder resist coating on the substrate and surrounding the copper foil; and
permanent mold coatings capable of coating on the copper foil;
wherein each copper foil define an opening, the opening is coated with solder resist, whereby the permanent mold coatings form a recess corresponding to the opening when coated on the copper foil.

2. The printed circuit board of claim 1, further comprising a plurality of copper tracks arranged on the substrate, where the copper tracks is used for linking electronic components soldered to the at least one pad.

3. The printed circuit board of claim 1, wherein the permanent mold coatings is solder paste.

4. The printed circuit board of claim 1, wherein the opening is defined in the middle of the copper foil.

5. The printed circuit board of claim 1, wherein the solder resist is green lacquer in the embodiment.

6. A method for manufacturing a printed circuit board, the printed circuit board comprising at least one pad for soldering an electronic component, the method comprising:
providing a substrate with copper foil bonded thereon;
designing a circuit pattern corresponding to the printed circuit board, wherein the circuit pattern includes at least one pin corresponding to the at least one pad, each pin defines a vacancy corresponding to the opening of the at least one pad;
converting the circuit pattern to a printed circuit mask, and covering the printed circuit mask on the surface of the substrate with copper foil and further coating with a layer of positive photoresist material thereon, and further being exposed to an intense ultraviolet light;
etching the substrate to leave the desired pattern including copper tracks and at least one pad having a copper foil with an opening defined therein;
coating the solder resist surrounding each pad and further on the opening;
coating permanent mold coatings on the copper foil to form a recess corresponding to the opening; and
positioning the leads of the electronic component in the recess and further melting the leads with the at least one pad.

7. The method of claim 6, further comprising:
washing the substrate to remove any film from the tracks after being etched.

8. The method of claim 6, wherein the permanent mold coatings is solder paste.

9. The method of claim 6, wherein the solder resist is green lacquer.
